(19) United States
(12) Patent Application Publication
(10) Pub. No.: US 2008/0160694 A1
(43) Pub. Date: Jul. 3, 2008

(54) METHOD FOR FORMING FLASH MEMORY DEVICE

(75) Inventor: Kwang Seon CHOI, Yongin-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/933,914

(22) Filed: Nov. 1, 2007

(30) Foreign Application Priority Data
Dec. 29, 2006 (KR) 10-2006-0137274

(51) Int. Cl. H01L 21/336

(52) U.S. Cl. 438/264; 257/E21.422

(57) ABSTRACT

A method for forming a flash memory device comprising forming a plurality of cell gate patterns in a cell area of a semiconductor substrate, forming a peripheral gate pattern, which includes a peripheral gate insulating layer and a peripheral gate electrode that are sequentially stacked, in a peripheral area of the semiconductor substrate, forming cell source and cell drain regions on the semiconductor substrate on each side of the cell gate patterns, forming peripheral source and peripheral drain regions on the semiconductor substrate on each side of the peripheral gate pattern, and forming a high density plasma USG layer over the semiconductor substrate such that the USG layer covers the cell gate patterns, the peripheral gate pattern, the cell source region, the cell drain region, the peripheral source region and the peripheral drain region.

### CROSS-REFERENCES AND RELATED APPLICATIONS

This application claims the benefit of Korean Patent Application No. 10-2006-0137274, filed on Dec. 29, 2006, which is hereby incorporated by reference in its entirety.

### BACKGROUND OF THE INVENTION

1. Field of the Invention

The present invention relates to a flash memory device. More particularly, the present invention relates to a method for forming a flash memory device.

2. Discussion of the Related Art

The differences in height in the surface of a semiconductor substrate that are formed during the manufacturing process reduce the manufacturing tolerances in semiconductor processes. For example, the height differences may reduce the focus margin of photolithography processes. Additionally, the height differences may also create spaces with high aspect ratios, which degrade the ability of a material layer to adequately coat the uneven surface, thereby causing problems such as gaps in the material layer Furthermore, as semiconductor devices have become more integrated, the problems caused by height differences have become even more difficult.

One suggested solution to the height difference problems is a process wherein the uneven surface is flattened using a material such as BPSG, PSG, or BSG. More specifically, an annealing process is performed after a BPSG, PSG, or BSG layer is deposited, causing the boron or phosphorus in the layer to flatten the layer. Advantageously, this method also makes it easy to fill gaps with high aspect ratios.

Reference will now be made to FIGS. 1 and 2, which illustrate a conventional method for forming a flash memory device using the flattening process mentioned above. As shown in FIG. 1, the semiconductor substrate 10 includes a cell area “a” and a peripheral area “b”. A plurality of cell gate patterns 12 are formed on the semiconductor substrate 10 in the cell area “a”. Each of the cell gate patterns 12 includes a tunnel oxide layer, a floating gate, an ONO layer, and a control gate electrode which are sequentially stacked on the semiconductor substrate 10.

In addition, a peripheral gate pattern 14 is formed on the semiconductor substrate 10 in the peripheral area “b”, which includes a gate oxide layer and a gate electrode which are sequentially stacked on the substrate 10.

Next, cell source and drain regions 13a are formed on the semiconductor substrate 10 on each side of the cell gate patterns 12. Similarly, peripheral source and peripheral drain regions 13b are formed on the semiconductor substrate 10 on each side of the peripheral gate pattern 14.

Cell spacers 16 are then formed on the sidewalls of each cell gate pattern 12 and peripheral spacers 18 are formed on the sidewalls of the peripheral gate pattern 14. Then, a silicon nitride layer 20 is formed on the entire surface of the semiconductor substrate 10, so as to cover the substrate 10 and the cell gate pattern 12 and peripheral gate pattern 14.

Then, as shown in FIG. 2, a BPSG layer 22 is formed on the surface of the semiconductor substrate 10, cell gate pattern 12, and peripheral gate pattern 14 and an annealing process is performed to flatten the BPSG layer 22.

In the conventional method for forming a flash memory device, the silicon nitride layer 20 prevents the boron or phosphorus in the BPSG layer 22 from penetrating into the cell memory transistors of the cell gate patterns 12 or peripheral transistors of the peripheral gate patterns 14. Thus, in order for the flattening process to be performed on the BPSG layer 22, the silicon nitride layer 20 must be provided below the BPSG layer 22 so as to the prevent boron or phosphorus in the BPSG layer 22 from penetrating into cell memory transistors and peripheral transistors. Next, the silicon nitride layer 20 is typically used as an etch stop layer in order to form a contact hole.

One problem with the current method, however, is that forming the silicon nitride layer 20 increases the fabrication costs of semiconductor devices. Moreover, the as semiconductor devices become more highly integrated, the gaps between the cell gate patterns 12 are made smaller, making it increasingly difficult to adequately fill the spaces between the cell gate patterns 12. Thus, the silicon nitride layer 20 and the BPSG layer 22 may not adequately fill the gaps.

### BRIEF SUMMARY OF THE INVENTION

Accordingly, the present invention is directed to a method for forming a flash memory device that substantially obviates one or more problem, limitation, or disadvantage of the current art.

One advantage of the present invention is the ability to form a flash memory device using a process that adequately fills the gaps between cell gate patterns while preventing the penetration of impurities into the cell memory transistors and peripheral transistors.

Another advantage of the present invention is the ability to forming a flash memory device using a new insulating layer which adequately fills the gaps between cell gate patterns while preventing penetration of impurities into cell memory transistors and peripheral transistors during the surface flattening process.

To achieve these advantages, one aspect of the invention is a method for forming a flash memory device comprising forming a plurality of cell gate patterns in a cell area of a semiconductor substrate; forming a peripheral gate pattern comprising a peripheral gate insulating layer and a peripheral gate electrode which are sequentially stacked in a peripheral area of the semiconductor substrate; forming cell source and cell drain regions on the semiconductor substrate on each side the cell gate patterns; forming peripheral source and peripheral drain regions on the semiconductor substrate on each side of the peripheral gate pattern; and forming a high density plasma USG layer over the semiconductor substrate such that the metal layer covers the cell gate patterns, the peripheral gate pattern, the cell source region, the cell drain region, the peripheral source region and the peripheral drain region.

It is to be understood that both the foregoing general description and the following detailed description of the present invention are exemplary and explanatory and are intended to provide an explanation of the invention as claimed.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description, the claims, and in the appended drawings.

### BRIEF DESCRIPTION OF THE DRAWINGS

The accompanying drawings, which are included to provide a further understanding of the invention, and are incorporated in and constitute a part of this application. The drawings illustrate embodiment(s) of the invention and together with the description serve to explain the principle of the invention. In the drawings:

FIGS. 1 and 2 are cross-sectional views illustrating a method for forming a flash memory device known in the current art; and

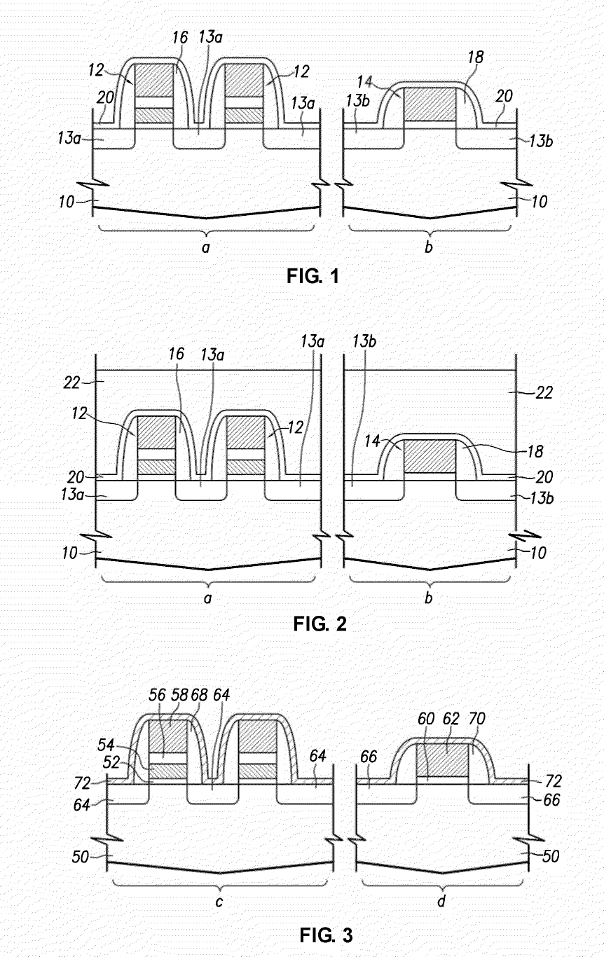

FIGS. 3 to 5 are cross-sectional views illustrating a method for forming a flash memory device according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

A method for forming a flash memory device according to the present invention uses a high density plasma Undoped Silicate Glass (USG) layer to fill any gaps between the cell gate patterns and peripheral gate patterns, including those with high aspect ratios.

In the present invention, a semiconductor substrate having a cell area and a peripheral area is prepared and a plurality of cell gate patterns are formed on the semiconductor substrate in the cell area. A peripheral gate pattern including a peripheral gate insulating layer and a peripheral gate electrode which are sequentially stacked are formed on the semiconductor substrate in the peripheral area.

Then, cell source and cell drain regions are formed on the semiconductor substrate on each side of each cell gate pattern and peripheral source and peripheral drain regions are formed on the semiconductor substrate on each side of the peripheral gate pattern. Then, a high density plasma USG layer is formed on the entire surface of the semiconductor substrate including over the cell gate patterns and peripheral gate pattern. In the illustrated example, each cell gate pattern includes a tunnel insulating layer, a floating gate, a blocking insulating pattern, and a control gate electrode which are sequentially formed on the substrate 10.

A flattening process is performed after gaps between the cell gate patterns have been filled with the high density plasma USG layer. Advantageously, the high density plasma USG layer is capable of preventing the penetration of impurities into the cell memory transistors and peripheral transistors because the plasma USG layer has not been doped with any impurities.

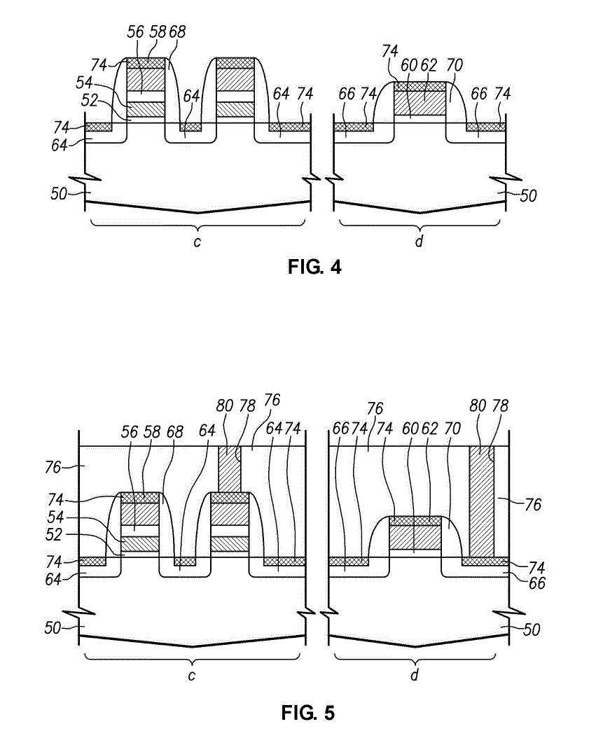

Reference will now be made to FIGS. 3 to 5 which illustrate an embodiment of the present invention comprising a method for forming a flash memory device.

As shown in FIG. 3, the semiconductor substrate 50 has a cell area “c” and a peripheral area “d”, with a plurality of cell gate patterns being formed on the semiconductor substrate 50 in the cell area “c”.

Each cell gate pattern includes a tunnel insulating layer 52, a floating gate 54, a blocking insulating pattern 56, and a control gate electrode 58, which formed are sequentially on the substrate 10.

The tunnel insulating layer 52 may be formed of an oxide layer, or more particularly, of a thermal oxide layer. The floating gate 54 may be formed of doped polysilicon, undoped polysilicon, or the like, and the blocking insulating pattern 56 may be formed of an oxide layer, an ONO layer, or a high-k layer. The control gate electrode 58 may be formed of a conducting material, such as a doped polysilicon material.

A peripheral gate pattern is formed on the semiconductor substrate 50 in the peripheral area “d”, which includes a peripheral gate insulating layer 60 and a peripheral gate electrode 62 which are formed sequentially on the substrate 10.

The peripheral gate insulating layer 60 may be formed of the same material and in the same process as the tunnel insulating layer 52. Alternatively, the peripheral gate insulating layer 60 may be formed after the tunnel insulating layer 52 is formed. The peripheral gate insulating layer 60 may also be formed to a thickness greater than the tunnel insulating layer 52.

Generally, the peripheral gate electrode 62 is formed of a conducting material. More particularly, the peripheral gate electrode 62 may be formed of doped polysilicon, and may be formed of the same material as the control gate electrode 58.

Cell source and cell drain regions 64 are formed on the semiconductor substrate 50 in the cell area “c” on each side of the cell gate patterns. Similarly, peripheral source and peripheral drain regions 66 are formed on the semiconductor substrate 50 in the peripheral area “d” on each side of the peripheral gate pattern.

The cell source/drain regions 64 and the peripheral source/drain regions 66 may be formed sequentially. Alternatively, the cell and peripheral source/drain regions 64 and 66 may be formed during the same process.

Cell spacers 68 are formed on the sidewalls of each cell gate pattern and peripheral spacers 70 are formed on the sidewalls of the peripheral gate pattern, and both the cell and peripheral spacers 68 and 70 are formed of an insulating material. For example, the cell and peripheral spacers 68 and 70 may be formed of at least one material selected from the group of an oxide material, a nitride material, and an oxide-nitride-oxide (ONO) material. The cell and peripheral spacers 68 and 70 may also be formed of different insulating materials.

A high dose of dopant ions may be implanted into the cell source and cell drain regions 64 after the spacers 68 and 70 are formed. Similarly, dopant ions may also be implanted into the peripheral source and peripheral drain regions 66. Accordingly, the cell and peripheral source/drain regions 64 and 66 may formed an LDD structure.

Next, a metal layer 72 is formed on the surface of the semiconductor substrate 50 and over the cell gate patterns and peripheral gate patterns. The metal layer 72 may be formed of cobalt, nickel, or titanium.

As shown in FIG. 4, a silicidation process is then performed on the semiconductor substrate 50. During the silicidation process, the metal layer 72 reacts with the control and peripheral gate electrodes 58 and 62 and the cell and peripheral source and drain regions 64 and 66. This reaction causes metal silicide regions 74 to form on the control gate electrode 58, the peripheral gate electrode 62, the cell source and cell drain regions 64, and the peripheral source and peripheral drain regions 66.

The silicidation process may be a heat treatment process The process for forming the metal layer 72 and the silicidation process may be performed in situ. Then any portion of the metal layer 72 which has not reacted during the silicidation process is removed to expose the metal silicide region 74.

As shown in FIG. 5, a high density plasma USG layer 76 is formed on the semiconductor substrate 50. Due to the excellent gap-filling characteristics of the high density plasma USG layer 76, the high density plasma USG layer 76 is able to adequately fill the gaps between the cell gate patterns even though the gaps have very high aspect ratios.

In this configuration, the high density plasma USG layer 76 is an insulating layer that has not been doped with impurities such as boron or phosphorus. Thus, the high density plasma USG layer can prevent penetration of impurities into cell memory transistors and peripheral transistors, which would otherwise exist when using the conventional BPSG, BSG, and/or PSG layers. Furthermore, an additional process for flattening the top surface of the high density plasma USG layer 76 may be performed after the high density plasma USG layer 76 is formed.

Then, at least one contact hole 78 is formed by forming the high density plasma USG layer 76 into a pattern. Preferably, the metal silicide regions 74 are used as an etch stop layer when the contact hole 78 is formed. That is, the contact hole 78 is formed on one of the control gate electrode 58, the peripheral gate electrode 62, the cell source and cell drain regions 64, and the peripheral source and peripheral drain regions 66.

The high density plasma USG layer 76 has high etch selectivity with respect to the metal silicide regions 74. Accordingly, the metal silicide regions 74 can be used effectively as an etch stop layer when the contact hole 78 is formed.

The contact hole 78 is formed on at least one area selected from the group of the control and peripheral gate electrodes 58 and 62 and the cell and peripheral source and drain regions 64 and 66. For example, the contact hole 78 may be formed on each of the electrodes 58 and 62 and the source and drain regions 64 and 66. Then, a contact plug 80 may be formed to fill the contact hole 78. Typically, the contact plug 80 is formed of a conducting material. For example, the contact plug 80 may comprise a metal such as tungsten.

As is apparent from the above description, the present invention provides a method for forming a flash memory device, which has a variety of features and advantages. For example, a flattening process is performed using a high density plasma USG layer, which has very excellent gap-filling characteristics. Accordingly, the high density plasma USG layer can adequately fill gaps between cell gate patterns even though the gaps have very high aspect ratios

In addition, the high density plasma USG layer has no impurities such as boron or phosphorus, meaning that the high density plasma USG layer can prevent penetration of impurities into cell memory transistors and peripheral transistors without forming a conventional silicon nitride layer. Since no conventional silicon nitride layer is formed, it is possible to reduce the fabrication costs of flash memory devices.

Further, the high density plasma USG layer has high etch selectivity with respect to the metal silicide regions formed on the control gate electrode, the peripheral gate electrode, the cell source and drain regions, and peripheral source and drain regions. Accordingly, the metal silicide regions may be used as an etch stop layer for forming a contact hole through the high density plasma USG layer.

It will be apparent to those skilled in the art that various modifications and variations can be made in the present invention without departing from the spirit or scope of the invention. Thus, the present invention is intended to cover the modifications and variations that come within the scope of the appended claims and their equivalents.

1. A method for forming a flash memory device, the method comprising:
forming a plurality of cell gate patterns on a cell area of a semiconductor substrate;
forming a peripheral gate pattern in a peripheral area of the semiconductor substrate, the peripheral gate pattern comprising a peripheral gate insulating layer and a peripheral gate electrode that are sequentially stacked on the semiconductor substrate in the peripheral area;
forming cell source and cell drain regions on each side of the cell gate patterns in the cell area of the semiconductor substrate;
forming peripheral source and peripheral drain regions on each side of the peripheral gate pattern in peripheral area of the semiconductor substrate; and
forming a high density plasma USG layer over the semiconductor substrate such that the USG layer covers the cell gate patterns, the peripheral gate pattern, the cell source region, the cell drain region, the peripheral source region and the peripheral drain region.

2. The method according to claim 1, wherein forming the cell gate patterns comprises forming sequentially forming a tunnel insulating layer, a floating gate, a blocking insulating pattern, and a control gate electrode on the surface of the cell area of semiconductor substrate.

3. The method according to claim 1, further comprising forming cell spacers on each sidewall of the cell gate patterns before forming the high density plasma USG layer.

4. The method according to claim 1, further comprising forming cell spacers on each sidewall of the peripheral gate pattern before forming the high density plasma USG layer.

5. The method according to claim 1, wherein, prior to forming the high density plasma USG layer, the method further comprises:
forming cell spacers on each sidewall of the cell gate patterns and the peripheral gate pattern;
forming a metal layer over the semiconductor substrate such that the metal layer covers the cell gate patterns, the peripheral gate pattern, the cell source region, the cell drain region, the peripheral source region and the peripheral drain region;
performing a silicidation process on the metal layer and semiconductor substrate; and
removing any portion of the metal layer that has not reacted during the silicidation process.

6. The method according to claim 5, wherein metal silicide regions are formed during the silicidation process, such that silicide regions form on the cell source regions, the cell drain regions, the peripheral source regions, the peripheral drain regions, on a control gate electrode in each of the cell gate patterns, and on a peripheral gate electrode in the peripheral gate pattern.

7. The method according to claim 1, further comprising:
performing a silicidation process on the semiconductor substrate so as to form metal silicide regions on the cell source regions, the cell drain regions, the peripheral source regions, the peripheral drain regions, on a control gate electrode in each of the cell gate patterns, and on a peripheral gate electrode in the peripheral gate pattern;
forming the high density plasma USG layer into a pattern using the metal silicide regions as an etch mask so as to form at least one contact hole; and
forming a contact plug to fill the contact hole.

8. A method for forming a flash memory device, the method comprising:
forming a plurality of cell gate patterns on a surface of a cell area a semiconductor substrate, the cell gate patterns comprising a tunnel insulating layer, a floating gate, a blocking insulating pattern, and a control gate electrode that are sequentially stacked on the semiconductor substrate in the cell area;
forming a peripheral gate pattern in a peripheral area of the semiconductor substrate, the peripheral gate pattern comprising a peripheral gate insulating layer and a peripheral gate electrode that are sequentially stacked on the semiconductor substrate in the peripheral area;
forming cell source and cell drain regions on each side of the cell gate patterns in the cell area of the semiconductor substrate;
forming peripheral source and peripheral drain regions on each side of the peripheral gate pattern in peripheral area of the semiconductor substrate;
forming cell spacers on each sidewall of the cell gate patterns and the peripheral gate pattern; and
forming a high density plasma USG layer over the semiconductor substrate such that the USG layer covers the cell gate patterns, the peripheral gate pattern, the cell source region, the cell drain region, the peripheral source region and the peripheral drain region.

9. The method according to claim 8, wherein, prior to forming the high density plasma USG layer, the method further comprises:
forming cell spacers on each sidewall of the cell gate patterns and the peripheral gate pattern;
forming a metal layer over the semiconductor substrate such that the metal layer covers the cell gate patterns, the peripheral gate pattern, the cell source region, the cell drain region, the peripheral source region and the peripheral drain region;
performing a silicidation process on the metal layer and semiconductor substrate; and
removing any portion of the metal layer that has not reacted during the silicidation process.

10. The method according to claim 8, wherein metal silicide regions are formed during the silicidation process, such that silicide regions form on the cell source regions, the cell drain regions, the peripheral source regions, the peripheral drain regions, on a control gate electrode in each of the cell gate patterns, and on a peripheral gate electrode in the peripheral gate pattern.

11. The method according to claim 8, further comprising:
performing a silicidation process on the semiconductor substrate so as to form metal silicide regions on the cell source regions, the cell drain regions, the peripheral source regions, the peripheral drain regions, on a control gate electrode in each of the cell gate patterns, and on a peripheral gate electrode in the peripheral gate pattern;
forming the high density plasma USG layer into a pattern using the metal silicide regions as an etch mask so as to form at least one contact hole; and
forming a contact plug to fill the contact hole.
